(19) United States
(12) Patent Application Publication
(10) Pub. No.: US 2024/0071846 A1
(43) Pub. Date: Feb. 29, 2024

(54) TEST KEY TRANSISTOR FOR DEEP TRENCH ISOLATION DEPTH DETECTION

(71) Applicant: CISTA SYSTEM CORP., Grand Cayman (KY)

(72) Inventors: Jingyi BAI, SAN JOSE, CA (US); Bo-Ray LEE, NEW TAIPEI CITY (TW)

(21) Appl. No.: 17/897,725

(22) Filed: Aug. 29, 2022

(51) Int. Cl. H01L 21/66; G01R 31/26; H01L 27/146

(52) U.S. Cl. CPC H01L 22/34; G01R 31/2621; H01L 27/1463

(57) ABSTRACT

This application describes systems and methods for detecting depth in deep trench isolation with semiconductor devices using test key transistors. An example semiconductor device comprises a test key transistor comprising a source, a drain, a channel connected to the source and the drain, and a gate; and a deep trench isolation encroaching into the channel of the test key transistor, wherein: the test key transistor is associated with a specification including a preset gate voltage, a preset source-drain voltage difference, and a predetermined current, and the test key transistor is configured to generate a current within a threshold difference from the predetermined current in the channel in response to receiving the preset gate voltage at the gate and the preset source-drain voltage difference at the source and the drain, and the deep trench isolation encroaches into the channel at a preset depth.

### TECHNICAL FIELD

The disclosure relates generally to deep trench isolations in semiconductor devices.

### BACKGROUND

A trench isolation is a semiconductor feature that can prevent electric current leakage between adjacent semiconductor components. A trench isolation can be a shallow trench isolation (STI) or a deep trench isolation (DTI). The DTI can generally be used on complementary metal-oxide semiconductor (CMOS) image sensors. When used in image sensors, DTIs can effectively suppress electrical and optical crosswalks, and make photodiodes in pixels taller, which can increase capacity per area. The depth of the DTIs can affect an overall performance of CMOS image sensors. Currently, there is no semiconductor device that can efficiently determine the depth of the DTIs during manufacturing or operations of the CMOS image sensors.

### SUMMARY

Various embodiments of the present specification may include hardware circuits, systems, methods for efficient memory allocation for sparse matrix multiplications.

According to one aspect, a semiconductor device comprises a test key transistor comprising a source, a drain, a channel connected to the source and the drain, and a gate; and a deep trench isolation encroaching into the channel of the test key transistor, wherein: the test key transistor is associated with a specification including a preset gate voltage, a preset source-drain voltage difference, and a predetermined current, and the test key transistor is configured to generate a current within a threshold difference from the predetermined current in the channel in response to receiving the preset gate voltage at the gate and the preset source-drain voltage difference at the source and the drain, and the deep trench isolation encroaches into the channel at a preset depth.

In some embodiments, the test key transistor is configured to generate, in the channel, a current more than a threshold difference from the predetermined current in response to the deep trench isolation encroaching into the channel at a depth that is smaller than the preset depth.

In some embodiments, the semiconductor device is configured to be determined as defective in response to the test key transistor generating the current more than the threshold difference from the predetermined current.

In some embodiments, the predetermined current is equal to 0 A, and the threshold difference is equal to 1 nA.

In some embodiments, the test key transistor further comprises an insulation layer below the gate, and the insulation layer is configured to reduce a cross-sectional area of the channel.

In some embodiments, the test key transistor is located on a side of the deep trench isolation, and the test key transistor is configured to generate the predetermined current in the channel in response to receiving the preset gate voltage at the gate and the preset source-drain voltage difference at the source and the drain, and the side of the deep trench isolation encroaches into the channel at the preset depth.

In some embodiments, the semiconductor device further comprises a plurality of test key transistors, each test key transistor corresponding to one of a plurality of sections of the deep trench isolation, wherein: each of the plurality of test key transistors is configured to generate, in a channel of the each test key transistor, a current more than a threshold difference from the predetermined current in response to the section of the deep trench isolation encroaching into the channel at a depth that is smaller than the preset depth, and determining that the semiconductor device is defective in response to any of the plurality of test key transistors generating the current more than the threshold difference from the predetermined current.

In some embodiments, the test key transistor is located on a corner of the deep trench isolation, and the test key transistor is configured to generate the predetermined current in the channel in response to receiving the preset gate voltage at the gate and the preset source-drain voltage difference at the source and the drain, and the corner of the deep trench isolation encroaches into the channel at the preset depth.

In some embodiments, the semiconductor device is a complementary metal-oxide semiconductor image sensor, the channel comprises photodiode, and the deep trench isolation is configured to provide isolation between pixels of the complementary metal-oxide semiconductor image sensor.

In some embodiments, the test key transistor is a p-type junction-gate field transistor or an n-type junction-gate field transistor.

According to another aspect, a method comprises applying a preset gate voltage on a gate of a test key transistor in a semiconductor device; applying a preset source-drain voltage difference on a source and a drain of the test key transistor; measuring a current flowing through a channel of the test key transistor in response to the applied preset gate voltage and preset source-drain voltage difference, wherein the channel is between the source and the drain of the test key transistor; comparing the measured current with a predetermined current of the test key transistor, wherein the predetermined current corresponds to the preset gate voltage and a preset depth of a deep trench isolation in the semiconductor device and the deep trench isolation encroaches into the channel; determining whether the deep trench isolation encroaching into the channel at a depth that is different from the preset depth according to the comparison between the measured current and the predetermined current; and determining that the semiconductor device is defective in response to the deep trench isolation having a different depth from the preset depth.

In some embodiments, determining whether the deep trench isolation encroaching into the channel a depth that is different from the preset depth according to the comparison between the measured current and the predetermined current comprises: determining that the measured current is not within a threshold difference from the predetermined current; and determining that the deep trench isolation encroaches into the channel at a depth that is different from the preset depth in response to the determination that the measured current is not within the threshold difference from the predetermined current.

In some embodiments, the predetermined current is equal to 0 A, and the threshold difference can be in a range between 1 nA and 1 μA.

In some embodiments, the semiconductor device comprises a plurality of the test key transistors, each test key transistor corresponding to one of a plurality of sections of the deep trench isolation, and determining that the semiconductor device is defective in response to the deep trench isolation encroaching into the channel at a different depth from the preset depth further comprises: determining that the semiconductor device is defective in response to any of the plurality of sections encroaching into the channel at a different depth from the predetermined depth.

In some embodiments, the plurality of sections of the deep trench isolation comprises one or more corners of the deep trench isolation.

In some embodiments, the plurality of sections of the deep trench isolation comprises one or more sides of the deep trench isolation.

In some embodiments, the test key transistor further comprises an insulation layer below the gate, and the insulation layer is configured to reduce a cross-sectional area of the channel.

In some embodiments, the semiconductor device is a complementary metal-oxide semiconductor image sensor, the channel comprises photodiode, and the deep trench isolation is configured to provide isolation between pixels of the complementary metal-oxide semiconductor image sensor.

In some embodiments, the test key transistor is a p-type junction-gate field transistor or an n-type junction-gate field transistor.

According to another aspect,

Embodiments of this specification provide systems and methods for detecting defects in semiconductor devices using effective and efficient JFET-like test keys. The test keys can be applied to any section of a DTI structure in the semiconductor device, such as DTI corners or sides, to determine whether the section reaches a preset DTI depth in the semiconductor device. The test keys can have a specification with a preset source-drain voltage difference, a preset gate voltage, and a predetermined current based on the preset DTI depth. The test keys can have flexible designs based on different preset DTI depths, such as adding or adjusting a well structure under the gate or adjusting the preset gate voltage applied on the gate.

Embodiments of this application provide systems and methods for detecting defects in DTIs within semiconductor devices using effective and efficient JFET-like test key transistors. The test keys can be applied to any section of a DTI structure in the semiconductor device, such as DTI corners or sides, to determine whether the section reaches a preset DTI depth in the semiconductor device. The test keys can have a specification with a preset source-drain voltage difference, a preset gate voltage, and a predetermined current based on the preset DTI depth. The test keys can have flexible designs based on different preset DTI depths, such as adding or adjusting an insulation layer under the gate or adjusting the preset gate voltage applied on the gate.

These and other features of the systems, methods, and hardware devices disclosed, and the methods of operation and functions of the related elements of structure and the combination of parts and economies of manufacture will become more apparent upon consideration of the following description and the appended claims referring to the drawings, which form a part of this specification, where like reference numerals designate corresponding parts in the figures. It is to be understood, however, that the drawings are for illustration and description only and are not intended as a definition of the limits of the invention.

### BRIEF DESCRIPTION OF THE DRAWINGS

FIG. 1A is a schematic of an example junction-gate field transistor, according to some embodiments of this specification.

FIG. 1B is a schematic of an example junction-gate field transistor with an applied gate voltage, according to some embodiments of this specification.

FIG. 2 is a schematic of an example backside illumination image sensor with deep trench isolation, according to some embodiments of this specification.

FIG. 3A is a schematic of an example test key transistor used in measuring deep trench isolation depth, according to some embodiments of this specification.

FIG. 3B is a schematic of an example test key transistor used in measuring deep trench isolation depth with an applied gate voltage, according to some embodiments of this specification.

FIG. 4 is a schematic of an example test key transistor used in measuring deep trench isolation depth with channel insulation, according to some embodiments of this specification.

FIG. 5 is a schematic of an example deep trench isolation structure having one or more sides and corners, according to some embodiments of this specification.

FIG. 6 is a schematic of an example test key transistor used in measuring deep trench isolation depth of a side deep trench isolation, according to some embodiments of this specification.

FIG. 7 is a schematic of an example test key transistor used in measuring deep trench isolation depth of a corner deep trench isolation, according to some embodiments of this specification.

FIG. 8 is a flowchart of an example method for testing deep trench isolation depth of a semiconductor device using a test key transistor, according to some embodiments of this specification.

### DETAILED DESCRIPTION

The specification is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present specification. Thus, the specification is not limited to the embodiments shown but is to be accorded the widest scope consistent with the principles and features disclosed herein.

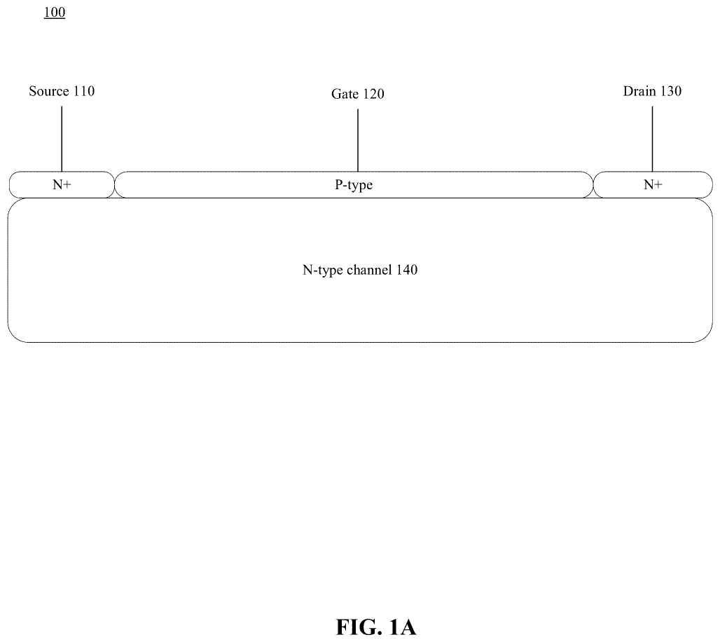

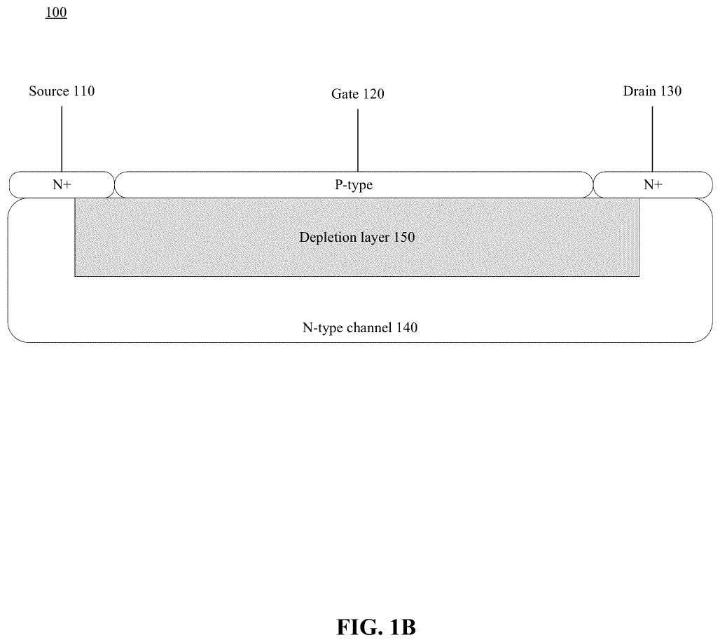

A field-effect transistor (FET) is a transistor that uses an electric field in controlling a flow of a current in a semiconductor. A junction-gate field transistor (JFET) is a FET that is voltage-controlled. FIG. 1A is a schematic of an example junction-gate field transistor, according to some embodiments of this specification. The schematic in FIG. 1 is for illustrative purposes only, and a JFET 100 shown in FIG. 1A may have fewer, more, and alternative components and connections depending on the implementation.

As shown in FIG. 1A, a JFET 100 comprises a source 110, a gate 120, a drain 130, and a channel 140. A voltage difference between source 110 and drain 130 causes electric charges (e.g., a current) to flow from source 110 to drain 130. For example, a drain voltage Vd can be applied on drain 130, and a source voltage Vs can be applied on source 110. When the drain voltage Vd is higher than the source voltage Vs (e.g., Vs is ground voltage and Vd is higher than the ground voltage), negative electric charges flows from source 110 to drain 130.

The flow of negative electric charges or current can be controlled by applying a reverse voltage on gate 120. FIG. 1B is a schematic of an example junction-gate field transistor with an applied gate voltage, according to some embodiments of this specification. JFET 100 shown in FIG. 1B is similar to JFET 100 shown in FIG. 1A. The schematic in FIG. 1B is for illustrative purposes only, and JFET 100 shown in FIG. 1B may have fewer, more, and alternative components and connections depending on the implementation.

As shown in FIG. 1B, a gate voltage Vg is applied to gate 120. The gate voltage Vg can be lower than the source voltage (e.g., the source voltage Vs is ground voltage and the gate voltage Vg is lower than the ground voltage) or higher than the source voltage (e.g., for special estimations). As a result, a depletion layer or depletion region 150 can be created or further extended in N-type channel 140 (e.g., extended from an intrinsic depletion region). Depletion layer 150 can encroach upon N-type channel 140 and restrict its cross-sectional area, thus hinder the flow of negative electric charges between source 110 and drain 130. Depletion layer 150's width can vary based on the gate voltage Vg applied on gate 120. Sometimes, when the applied gate voltage Vg is low enough (e.g., more negative than the source voltage), depletion layer 150 can pinch-off N-type channel 140, effectively stops the flow of negative electric charges. For example, when the depletion layer 150's width spans or nearly spans the width of N-type channel 140, the flow of negative electric charges stops.

It is appreciated that JFET 100 shown in FIGS. 1A and 1B has an N-type channel. A person skilled in the art can appreciate that JFET 100 can have a P-type channel instead. For purposes of simplicity, JFET 100 is demonstrated as having an N-type channel, unless otherwise stated.

Digital cameras, scanners, and other imaging devices often use image sensors, such as charge-coupled device (CCD) image sensors or complementary metal-oxide semiconductor (CMOS) image sensors, to convert optical signals to electrical signals. An image sensor can typically include a grid of pixels including photodiodes, row access circuitry, column access circuitry, and a ramp signal generator. The pixels capture the light impinged on them and convert the light signals to electrical signals. The row access circuitry controls which row of pixels that the sensor will read. The column access circuitry includes column read circuits that read the signals from corresponding columns. The ramp signal generator generates a ramping signal as a global reference signal for column read circuits to record the converted electrical signal.

A trench isolation is a semiconductor feature that can prevent electric current leakage between adjacent semiconductor components. A trench isolation can be a shallow trench isolation (STI) or a deep trench isolation (DTI). The STI can generally be used on CMOS process technology nodes (e.g., 250 nanometers or smaller). The STI can be suitable for increased density requirements, since it allows forming of smaller isolation regions. The DTI typically has more depth. For example, The DTI can be 0.1 to 1 μm in width and 2 to 5 μm in depth. The DTI can be used in CMOS image sensors.

When used in image sensors (e.g., CMOS image sensors), DTIs can make photodiodes taller, which can increase capacity per area and increasing an overall effectiveness of the image sensors in capturing incoming light. For example, for Si-based photodiodes, DTI can be filled with lower refractive index materials, effectively blocking the electrical crosstalk in deep quasi-neutral region and optical crosstalk through the active Si layers.

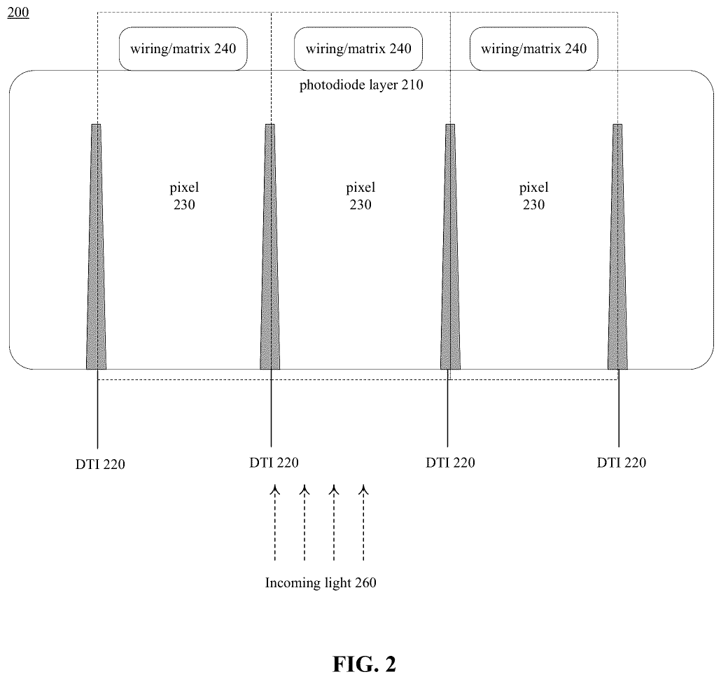

DTIs can be especially useful for back-illuminated or backside illumination (BSI) CMOS image sensors. BSI sensors can allow wirings and matrix of the sensors to be placed behind the photodiode layer away from the incoming lights, so that the incoming lights can strike the photodiode layer without passing through the wirings and the matrix. Since the wirings and the matrix are not in the way, the BSI sensors can improve an amount of the incoming lights being captured by the photodiode layer. FIG. 2 is a schematic of an example backside illumination image sensor with deep trench isolation, according to some embodiments of this specification. The schematic in FIG. 2 is for illustrative purposes only, and an image sensor 200 shown in FIG. 2 may have fewer, more, and alternative components and connections depending on the implementation.

As shown in FIG. 2, image sensor 200 comprises a photodiode layer 210. Photodiode layer 210 can include photodiodes. Photodiode layer 210 is separated by one or more DTIs 220, and the separations can create a number of pixels 230. Since DTIs 220 has a higher depth encroaching into photodiode layer 210, pixels 230 can operate with a higher depth, increasing capacity per area for image sensor 200. Pixels 230 captures incoming light 260, which strikes the pixels from the bottom direction. Image sensor 200 can further comprise one or more wiring or matrix 240, located behind photodiode layer 210 and away from the direction of incoming light 260. Although DTIs 220 are shown in a trapezoid shape, it is appreciated that DTIs 220 can take any reasonable shapes to provide separations between pixels 230, such as a rectangular shape or a rectangular shape with a round finish at an end. In some embodiments, image sensor 200 can be a CMOS image sensor.

When the DTI is used in semiconductor devices (e.g., in CMOS image sensors such as image sensor 200 of FIG. 2), the depth of the DTI needs to be measured during the testing (e.g., manufacturing testing) or operation process of the semiconductor devices to ensure the full functionality of the DTI in the semiconductor devices. For example, if the depth of the DTI is not encroaching the photodiode layer deep enough, the DTI may not provide effective blocking of the electrical or optical crosstalk between pixels. However, currently there is not a reliable and efficient method or device (e.g., a test key) in measuring the DTI's depth in a semiconductor device.

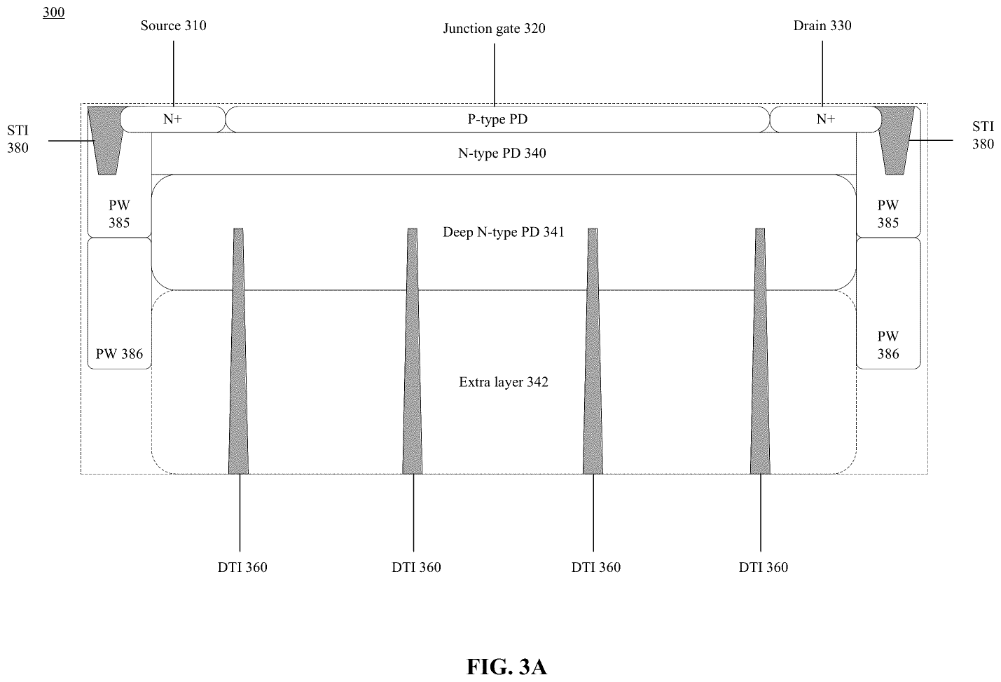

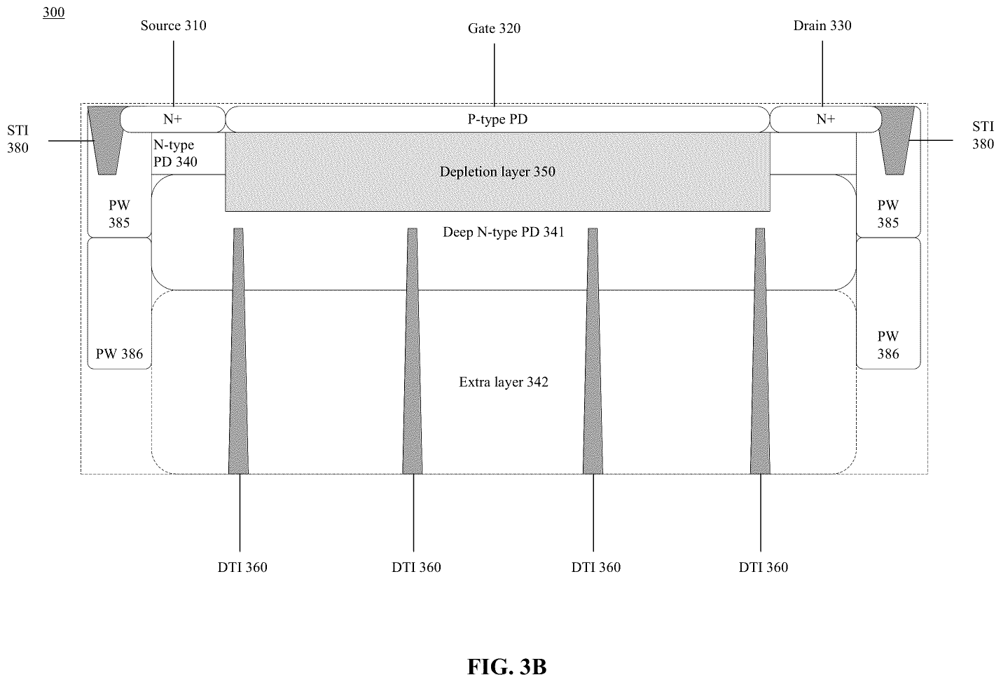

Embodiments of the specification provide novel methods and devices to measure depths of DTIs in semiconductor devices, such as in CMOS image sensors. FIG. 3A is a schematic of an example test key transistor in measuring deep trench isolation depth, according to some embodiments of this specification. The schematic in FIG. 3A is for illustrative purposes only, and a test key transistor 300 shown in FIG. 3A may have fewer, more, and alternative components and connections depending on the implementation.

In some embodiments, test key transistor 300 shown in FIG. 3A is a part of a semiconductor device, and test key transistor 300 can be similar to JFET 100 shown in FIG. 1A or FIG. 1B. As shown in FIG. 3A, test key transistor 300 comprises a source 310 (e.g., similar to source 110 of FIG. 1A or FIG. 1B), a gate 320 (e.g., similar to gate 120 of FIG. 1A or FIG. 1B), and a drain 330 (e.g., similar to drain 130 of FIG. 1A or FIG. 1B). In some embodiments, test key transistor 300 has an N-type channel, and gate 320 is p-type. For example, test key transistor 300 comprises N-type channel (e.g., N-type photodiode) 340 and deep N-type channel (e.g., deep N-type photodiode) 341. N-type photodiode 340 and deep N-type channel 341 can be made of a same type of material (e.g., silicon) or different types of materials. In some embodiments, deep N-type channel 341 can use higher energy or lighter dopant type to implant than N-type photodiode 340. In some embodiments, N-type photodiode 340 or deep N-type channel 341 can be similar to photodiode layer 210 of FIG. 2. For example, if the semiconductor device is a CMOS image sensor, N-type photodiode 340 and deep N-type channel 341 can be photodiodes. In some embodiments, one or more DTIs 360 (e.g., similar to DTIs 220 of FIG. 2) can encroach into N-type photodiode 340 or deep N-type channel 341, creating pixels (e.g., pixels 230 of FIG. 2). In some embodiments, at least some parts of test key transistor 300 can be a part of wiring/matrix 240 of FIG. 2. For example, source 310, gate 320, and drain 330 can be parts of wiring/matrix 240 shown in FIG. 2, and located away from the direction of incoming light 260. In some embodiments, test key transistor 300 can be insulated, such as using STIs 380 near source 310 and drain 330. In some embodiments, test key transistor 300 can be insulated using p-type wells 385 and 386. P-type wells 385 and 386 can be made of a same type of material with different implantations. In some embodiments, test key transistor 300 further comprises one or more extra layers 342 located below deep N-type channel 341. For example, extra layers 342 can be a deeper N-type well. In some embodiments, N-type photodiode 340, deep N-type channel 341, and extra layers 342 can form a very deep channel (e.g., between ten times and a thousand times deeper than a traditional FET).

As shown in FIG. 3A, when a gate voltage is applied to gate 320, a depletion layer or depletion region can be created in N-type photodiode 340 or deep N-type channel 341. FIG. 3B is a schematic of an example test key transistor used in measuring deep trench isolation depth with an applied gate voltage, according to some embodiments of this specification. It is appreciated that test key transistor 300 shown in FIG. 3B is similar to JEFT 300 shown in FIG. 3A. The schematic in FIG. 3B is for illustrative purposes only, and test key transistor 300 shown in FIG. 3B may have fewer, more, and alternative components and connections depending on the implementation.

As shown in FIG. 3B, a depletion layer 350 can encroach upon N-type photodiode 340 or deep N-type channel 341, which serves as an N-type channel for test key transistor 300. Depletion layer 350 can restrict a cross-sectional area of N-type photodiode 340 or deep N-type channel 341, thus hinder the flow of current (e.g., negative electric charges) between source 310 and drain 330. Depletion layer 350's depth can vary based on the gate voltage applied on gate 320. When the applied gate voltage is low enough, depletion layer 350 can get close to or reach the depth of DTI, effectively pinching-off the N-type channel, causing the flow of negative electric charges to be 0 or close to 0. As a result, by adjusting the gate voltage and measuring the current (e.g., the flow of negative electric charges) between source 310 and drain 330, the depth of DTI 360 can be measured. For example, a preset depth of DTI 360 (e.g., representing an designed depth of DTIs in the semiconductor device) can be determined first. When the gate voltage is applied on gate 320, the gate voltage can be adjusted so that the depth of depletion layer 350 can reach or get close to the preset depth of DTI 360, which supposedly results in a pinch-off of the N-type channel. If enough current can still be detected between source 310 and drain 330, or if the current between source 310 and drain 330 exceeds a threshold, it can be determined that the actual depth of DTI 360 may not have reached the preset depth. As a result, the semiconductor device can be determined to be defective, since at least one or more DTIs are not deep enough to provide effective isolation between pixels.

In some embodiments, the gate voltage can be a preset voltage, and a depth of depletion layer 350 created based on the preset gate voltage can be predetermined. Given the preset depth of DTI 360, a predetermined current between source 310 and drain 330 can be predetermined based on the predetermined depth of depletion layer 350. As a result, if the actual measured current between source 310 and drain 330 does not match with or is not close to the predetermined current, it can be determined that the actual depth of one or more DTIs does not match or is not close to the preset DTI depth. Therefore, the semiconductor device can be determined to be defective, since at least one or more DTIs are not at the preset depth. The DTIs may not provide effective isolation between pixels.

As shown in FIG. 3A and FIG. 3B, test key transistor 300 can be used to measure the depth of DTIs. As a test key, test key transistor 300 can have a specification with a preset source-drain voltage difference, a preset gate voltage, and a predetermined current. For example, test key transistor 300 can have the following test key specification: a source voltage is ground, a drain voltage is 0.5V (e.g., the preset source-drain voltage difference), a preset gate voltage is −1V, and when these voltages are applied, an absolute value of a predetermined current between source 310 and drain 330 should be equal to 0 or within a threshold difference from 0 (e.g., lower than 1 nA, in a range between 1 nA and 1 μA, etc.). If the current is measured to be higher than the threshold difference, the DTIs may have a depth that is not deep enough to cause a pinch-off of the N-type channel, and the semiconductor device may be determined to be defective due to the insufficient DTI depth.

It is appreciated that test key transistor 300 shown in FIG. 3A or FIG. 3B has an n-type channel. A person skilled in the art can appreciate that test key transistor 300 can have a p-type channel instead. For example, test key transistor 300 can comprise p-type channel 340 or deep p-type channel 341, a p+ source 310, and a p+ drain 330, and gate 320 can be n-type. For purposes of simplicity, test key transistor 300 is demonstrated as having an n-type channel, unless otherwise stated.

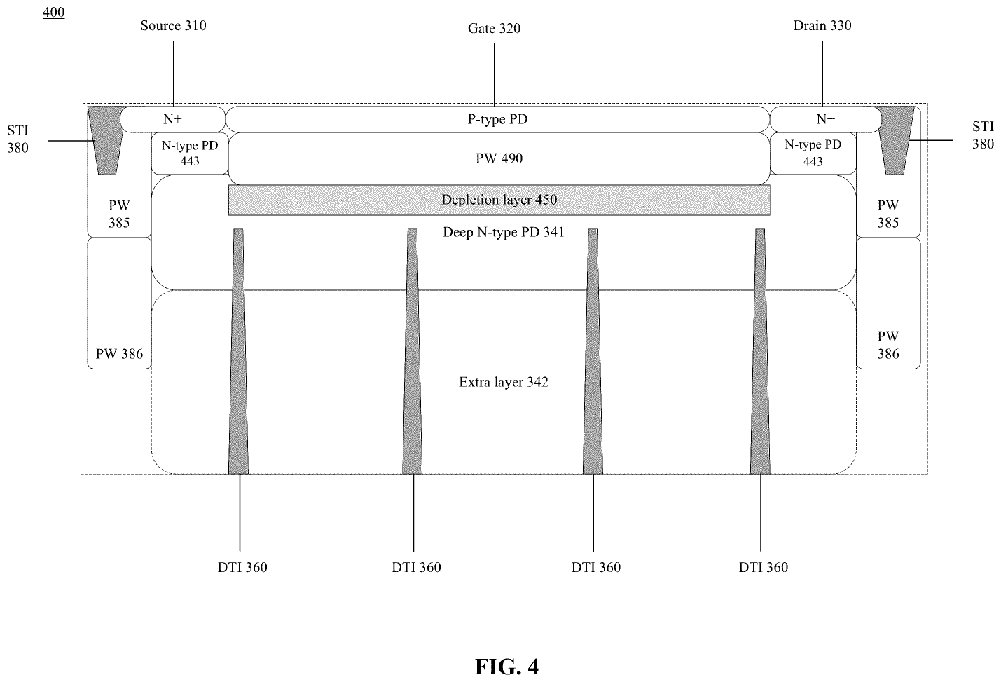

In some embodiments, gate 320 can have extra insulation into the channel (e.g., n-type photodiode 340 or deep n-type channel 341), so that a smaller gate voltage (e.g., closer to 0) is needed to determine the depth of the DTIs. FIG. 4 is a schematic of an example test key transistor used in measuring deep trench isolation depth with channel insulation, according to some embodiments of this specification. The schematic in FIG. 4 is for illustrative purposes only, and test key transistor 400 shown in FIG. 4 may have fewer, more, and alternative components and connections depending on the implementation.

In some embodiments, test key transistor 400 includes components similar to test key transistor 300 shown in FIG. 3A and FIG. 3B. For example, similar to test key transistor 300, test key transistor 400 comprises source 310, gate 320, drain 330, and deep n-type channel 341. One or more DTIs 360 (e.g., similar to DTIs 360 shown in FIG. 3A and FIG. 3B) encroach into deep n-type channel 341. In some embodiments, similar to test key transistor 300, test key transistor 400 further comprises one or more STIs 380 and p-type wells 385 and 386. In some embodiments, test key transistor 400 comprises an insulation layer (e.g., p-type well 490) located below gate 320, and N-type photodiodes 443 located below source 310 and drain 330. N-type photodiodes 443 connects source 310 and drain 330 with deep N-type channel 341, serving as an N-type channel for test key transistor 300 and allowing current to flow between source 310 and drain 330. P-type well 490 encroaches into the N-type channel formed by N-type photodiodes 443 and deep N-type channel 341, resulting in a decrease of the cross-sectional area of the N-type channel. When a gate voltage is applied, a depletion layer 450 is created below p-type well 490. Since the N-type channel already has a smaller cross-section area due to p-type well 490, depletion layer 450 can reach DTIs 360 with a depletion layer depth that is smaller than the depth of depletion layer 350 of FIG. 3B needed to reach or get close to DTIs 360. Therefore, a smaller gate voltage is needed to operate test key transistor 400 as a test key, making test key transistor 400 to operate more efficiently and effectively.

As shown in FIG. 4, test key transistor 400 can be used to measure the depth of DTIs. As a test key, test key transistor 400 can have a specification with a preset source-drain voltage difference, a preset gate voltage, and a predetermined current. Since test key transistor 400 includes p-well 490, the preset gate voltage of test key transistor 400 can be smaller (e.g., closer to 0) than the preset gate voltage of test key transistor 300. For example, test key transistor 400 can have the following test key specification: a source voltage is ground, a drain voltage is 0.5V (e.g., preset source-drain voltage difference), a preset gate voltage is −0.7V, and when these voltages are applied, an absolute value of a predetermined current between source 410 and drain 430 should be equal to 0 or within a threshold difference from 0 (e.g., lower than 1 nA, in a range between 1 nA and 1 μA, etc.). If the current is measured to be higher than the threshold difference, the DTIs may have a depth that is not deep enough to cause a pinch-off of the N-type channel, and the semiconductor device may be determined to be defective due to the insufficient DTI depth.

In some embodiments, DTIs 360 can have a smaller preset depth (e.g., due to system requirements of the semiconductor device). As a result, DTIs 360 may not encroach into the N-type channel as much, and the depth of p-type well 490 can be adjusted as a part of a design process for test key transistor 400 so that a reasonable gate voltage can be applied to allow the depletion layer 450 to reach or get close to DTIs 360 and determine the depth of DTIs 360. Therefore, as a part of the specification, the size or depth of the p-type well 490 can be designed based on the preset depth of DTIs 360.

It is appreciated that test key transistor 400 shown in FIG. 4 has an n-type channel. A person skilled in the art can appreciate that test key transistor 400 can have a p-type channel instead. For example, test key transistor 400 can include P-type photodiodes 443 and deep P-type channel 341, a p+ source 310, and a p+ drain 330, and gate 320 is N-type and the insulation layer is N-type. For purposes of simplicity, test key transistor 400 is demonstrated as having an n-type channel, unless otherwise stated.

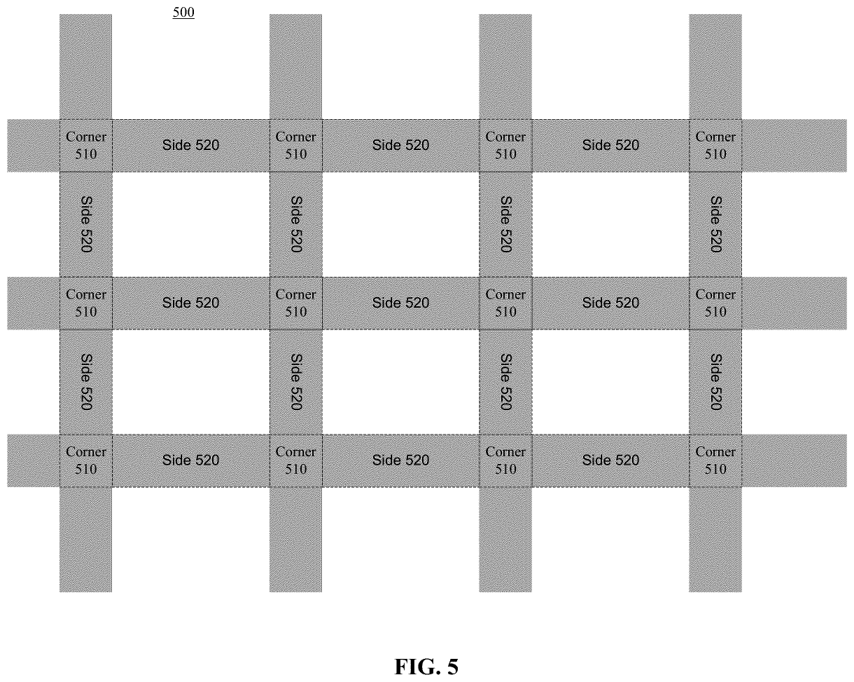

In some embodiments, DTIs 360 can have a structure that includes sides and corners. FIG. 5 is a schematic of an example deep trench isolation structure having one or more sides and corners, according to some embodiments of this specification. The schematic in FIG. 5 is for illustrative purposes only, and DTI structure 500 shown in FIG. 5 may have fewer, more, and alternative components and connections depending on the implementation.

In some embodiments, DTI structure 500 shown in FIG. 5 includes DTIs 360 shown in FIG. 3A, FIG. 3B, or FIG. 4. For example, DTI structure 500 is shown from a top or bottom view in FIG. 5, and DTIs 360 are shown from a side view in FIG. 3A, FIG. 3B, or FIG. 4. As shown in FIG. 5, each horizontal or vertical line of DTI structure 500 represents DTIs formed on a semiconductor device (e.g., CMOS image sensor such as image sensor 200 of FIG. 2). Horizontal lines of DTI can intersect with vertical lines of DTI, resulting in a corner of DTI structure 500. For example, as shown in FIG. 5, DTI structure 500 comprises a plurality of corners 510, with each corner 510 being at an intersection of a horizontal line and a vertical line. Parts of the horizontal and vertical lines of DTI structure 500 that are not corners can be represented as sides of DTI structure 500. For example, as shown in FIG. 5, DTI structure comprises a plurality of sides 520, with each side 520 being a section of horizontal or vertical lines between two corners 510.

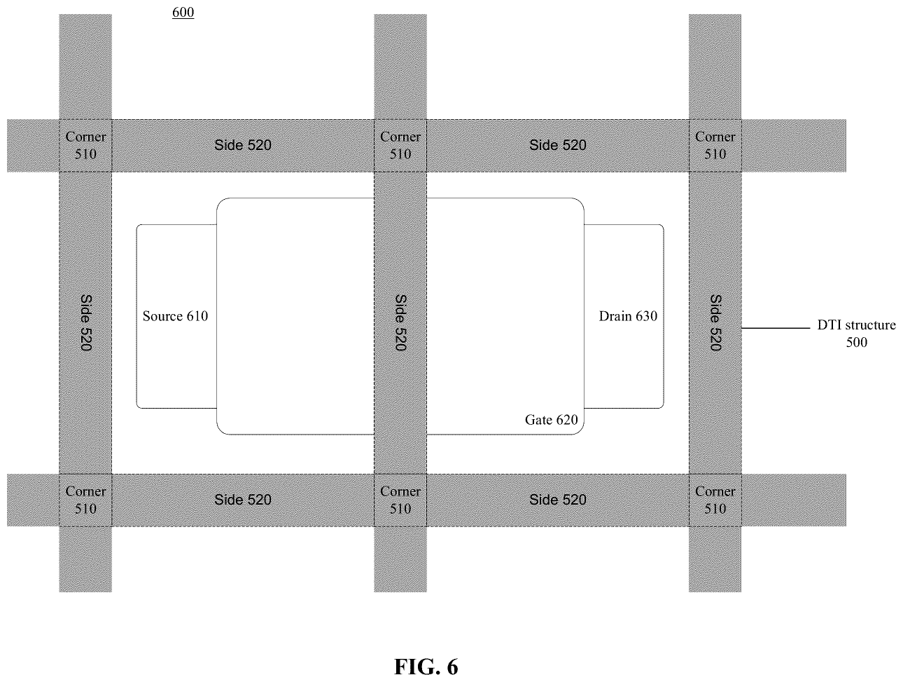

Corners 510 can have a DTI depth that is different from sides 520. For example, although DTI structure 500 can be designed to have a same DTI depth at corners 510 and sides 520, such uniform depth may not be fully achieved during manufacturing of the semiconductor device. As a result, DTI depth may need to be verified at corners 510 and sides 520 separately to determine whether the semiconductor device is defective due to abnormal DTI depth. In some embodiments, DTI structure 500 can be designed to have different DTI depths at corners 510 and sides 520, which needs a plurality of test key transistors configured differently with different specifications to accommodate for differences in DTI depths. FIG. 6 is a schematic of an example test key transistor used in measuring deep trench isolation depth of a side deep trench isolation, according to some embodiments of this specification. The schematic in FIG. 6 is for illustrative purposes only, and test key transistor 600 shown in FIG. 6 may have fewer, more, and alternative components and connections depending on the implementation.

As shown in FIG. 6, test key transistor 600 can be a test key for a semiconductor device (e.g., CMOS image sensor such as image sensor 200 of FIG. 2), comprising a source 610 (e.g., similar to source 310 of FIG. 3A, FIG. 3B, and FIG. 4), a gate 620 (e.g., similar to gate 320 of FIG. 3A, FIG. 3B, and FIG. 4), and a drain 630 (e.g., similar to drain 630 of FIG. 3A, FIG. 3B, and FIG. 4). Test key transistor 600 is located on a side 520 (e.g., sides 520 of FIG. 5) in a DTI structure 500 (e.g., DTI structure 500 of FIG. 5). In some embodiments, as shown in FIG. 6, DTI structure 500 and test key transistor 600 are shown from a bottom view, and DTIs 360 and test key transistor 300 are shown from a side view in FIG. 3A, FIG. 3B, or FIG. 4. Since test key transistor 600 is located on side 520, test key transistor 600 can be configured to measure the DTI depth of side 520, and determine whether the semiconductor device is defective due to the measurement of side 520.

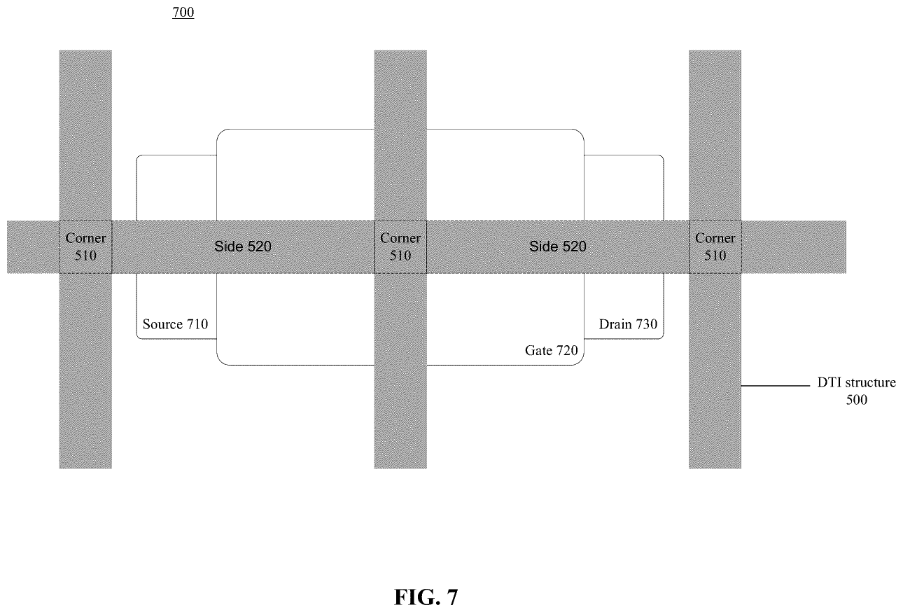

FIG. 7 is a schematic of an example test key transistor used in measuring deep trench isolation depth of a corner deep trench isolation, according to some embodiments of this specification. The schematic in FIG. 7 is for illustrative purposes only, and test key transistor 700 shown in FIG. 7 may have fewer, more, and alternative components and connections depending on the implementation.

As shown in FIG. 7, test key transistor 700 can be a test key for a semiconductor device (e.g., CMOS image sensor such as image sensor 200 of FIG. 2), comprising a source 710 (e.g., similar to source 310 of FIG. 3A, FIG. 3B, and FIG. 4), a gate 720 (e.g., similar to gate 320 of FIG. 3A, FIG. 3B, and FIG. 4), and a drain 730 (e.g., similar to drain 630 of FIG. 3A, FIG. 3B, and FIG. 4). Test key transistor 700 is located on a corner 510 (e.g., corners 510 of FIG. 5) in a DTI structure 500 (e.g., DTI structure 500 of FIG. 5). In some embodiments, as shown in FIG. 7, DTI structure 500 and test key transistor 700 are shown from a bottom view, and DTIs 360 and test key transistor 300 are shown from a side view in FIG. 3A, FIG. 3B, or FIG. 4. Since test key transistor 700 is located on corner 510, test key transistor 700 can be configured to measure the DTI depth of corner 510, and determine whether the semiconductor device is defective due to the measurement of corner 510. It is appreciated that the semiconductor device can have one or more test key transistors 600 shown in FIG. 6, one or more test key transistors 700 shown in FIG. 7, or both, as test keys for the semiconductor device's DTIs. In some embodiments, DTI structure 500 shown in FIG. 6 and FIG. 7 can have different design choices in DTI depth at different DTI sections. For example, some parts of DTI structure 500 (e.g., corners 510 or sides 520) can be configured to have a preset DTI depth that is different from that of some other parts of DTI structure 500. As a result, different test key transistors can be configured differently to accommodate different preset DTI depths in DTI structure 500. In some embodiments, if any of the test key transistors in the semiconductor device reports an abnormal DTI depth, or if a number of test key transistors in the semiconductor device reporting abnormal DTI depth reaches a threshold, the semiconductor device can be determined to be defective.

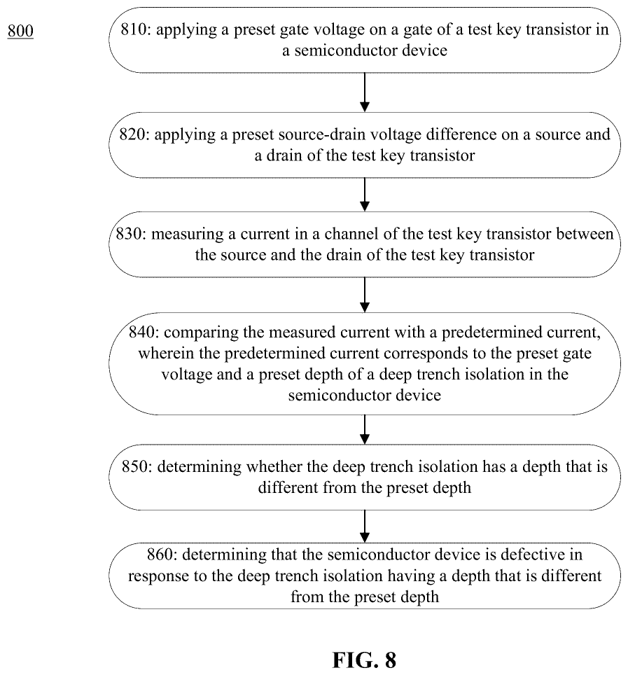

Embodiments of this specification provides a method for testing DTI depth using a test key transistor. FIG. 8 is a flowchart of an example method for testing deep trench isolation depth of a semiconductor device using a test key transistor, according to some embodiments of this specification. The method 800 may be implemented in an environment shown in FIG. 3A, FIG. 3B, FIG. 4, FIG. 6, and FIG. 7. The method 800 may be performed by a device, apparatus, or system illustrated by FIG. 3B, FIG. 4, FIG. 6, and FIG. 7. Depending on the implementation, the method 800 may include additional, fewer, or alternative steps performed in various orders or parallel.

Step 810 includes applying a preset gate voltage on a gate of a test key transistor in a semiconductor device. In some embodiments, the test key transistor can be similar to test key transistor 300 of FIG. 3A or FIG. 3B, test key transistor 400 of FIG. 4, test key transistor 600 of FIG. 6, or test key transistor 700 of FIG. 7. In some embodiments, the gate is similar to gate 320 of FIG. 3A, FIG. 3B, or FIG. 4, gate 620 of FIG. 6, or gate 720 of FIG. 7. In some embodiments, the preset gate voltage is a part of the test key transistor's specification, which can be used to determine an DTI depth of one or more DTIs in the semiconductor device and determine whether the semiconductor device is defective due to abnormal DTI depth. As a result, the preset gate voltage can be predetermined based on a preset DTI depth. In some embodiments, the DTIs in the semiconductor device has a DTI structure similar to DTI structure 500 shown in FIG. 5, FIG. 6, or FIG. 7. In some embodiments, similar to test key transistor 600 shown in FIG. 6, the test key transistor can be located on a DTI side (e.g., side 520 shown in FIG. 6) to determine DTI depth of the DTI side. In some embodiments, similar to test key transistor 700 shown in FIG. 7, the test key transistor can be located on a DTI corner (e.g., corner 510 shown in FIG. 7) to determine DTI depth of the DTI corner. In some embodiments, the applied preset gate voltage creates a depletion layer (e.g., depletion layer 350 shown in FIG. 3B or depletion layer 450 shown in FIG. 4) below the gate. In some embodiments, the semiconductor device can be a CMOS image sensor. As a result, the gate of the test key transistor can include photodiodes (e.g., similar to gate 320 shown in FIG. 3A, FIG. 3B, and FIG. 4).

Step 820 includes applying a preset source-drain voltage difference on a source and a drain of the test key transistor. In some embodiments, the source is similar to source 310 of FIG. 3A, FIG. 3B, or FIG. 4, source 610 of FIG. 6, or source 710 of FIG. 7. In some embodiments, the drain is similar to drain 330 of FIG. 3A, FIG. 3B, or FIG. 4, drain 630 of FIG. 6, or drain 730 of FIG. 7. In some embodiments, the preset source-drain voltage difference is a part of the test key transistor's specification in determining the DTI depth. For example, the source can be ground, and the drain receives a drain voltage of 0.5V, resulting in a preset source-drain voltage difference of 0.5V.

Step 830 includes measuring a current in a channel of the test key transistor between the source and the drain of the test key transistor in response to applying the preset source-drain voltage difference. For example, as shown in FIG. 3A and FIG. 3B, test key transistor 300 can have a specification with a source voltage being ground, a drain voltage being 0.5V (e.g., preset source-drain voltage difference), and a preset gate voltage being −1V. In some embodiments, if the depletion layer created by the applied gate voltage reaches or get close to the DTIs, there may not be any current flowing between the source and the drain. As a result, measuring the current between the source and the drain can result in a measurement of 0.

Step 840 includes comparing the measured current with a predetermined current. In some embodiments, the predetermined current is a part of the test key transistor's specification. As a result, the predetermined current can be predetermined based on a preset DTI depth and the preset gate voltage. For example, as shown in FIG. 3B, test key transistor 300 can have the following test key specification: a source voltage is ground, a drain voltage is 0.5V (e.g., preset source-drain voltage difference), a preset gate voltage is −1V, and when these voltages are applied, an absolute value of a predetermined current between source 310 and drain 330 should be equal to 0 or within a threshold difference from 0 (e.g., lower than 1 nA, in a range between 1 nA and 1 μA, etc.). If the current is measured to be higher than the threshold difference, the DTIs may have a depth that is not deep enough to cause a pinch-off of the N-type channel, and the semiconductor device may be determined to be defective due to the insufficient DTI depth. In some embodiments, the test key transistor includes an insulation layer near the gate (e.g., p-type well 490 of FIG. 4). As a result, the preset gate voltage of the test key transistor can be smaller (e.g., closer to 0) than the preset gate voltage of test key transistor 300. For example, as shown in FIG. 4, test key transistor 400 can have the following test key specification: a source voltage is ground, a drain voltage is 0.5V (e.g., preset source-drain voltage difference), a preset gate voltage is −0.7V, and when these voltages are applied, an absolute value of a predetermined current between source 410 and drain 430 should be equal to 0 or within a threshold difference from 0 (e.g., lower than 1 nA, in a range between 1 nA and 1 μA, etc.). If the current is measured to be higher than the threshold difference, the DTIs may have a depth that is not deep enough to cause a pinch-off of the N-type channel, and the semiconductor device may be determined to be defective due to the insufficient DTI depth. In some embodiments, DTIs 360 can have a smaller preset depth (e.g., due to system requirements of the semiconductor device). As a result, DTIs 360 may not encroach into the N-type channel as much, and the depth of the insulation layer (e.g., p-type well 490) can be adjusted as a part of a design process for the test key transistor so that a reasonable gate voltage can be applied to allow the depletion layer 450 to reach or get close to the DTI and determine the depth of DTI. Therefore, as a part of the specification, the size or depth of the p-type well 490 can be designed based on the preset depth of DTIs 360.

Step 850 includes determining whether the DTI has a depth that is different from the preset depth based on the comparison from step 830. In some embodiments, the DTI depth can be determined to be different from the preset depth when an absolute value of the measured current is higher than a threshold difference from the predetermined current.

Step 860 includes determining that the semiconductor device is defective in response to the deep trench isolation having a depth that is different from the preset depth. In some embodiments, the semiconductor device can have one or more test key transistors (e.g., test key transistor 600 shown in FIG. 6, test key transistor 700 shown in FIG. 7, or both). In some embodiments, DTI structure (e.g., DTI structure 500 shown in FIG. 6 and FIG. 7) of the semiconductor device can have different design choices in DTI depth at different DTI sections. For example, as shown in FIG. 6 and FIG. 7, some parts of DTI structure 500 (e.g., corners 510 or sides 520) can be configured to have a preset DTI depth that is different from that of some other parts of DTI structure 500. As a result, different test key transistors can be configured differently to accommodate different preset DTI depth in DTI structure 500. In some embodiments, if any of the test key transistors in the semiconductor device reports an abnormal DTI depth, or if a number of test key transistors in the semiconductor device reporting abnormal DTI depth reaches a threshold, the semiconductor device can be determined to be defective.

Embodiments of this application provide systems and methods for detecting defects in DTIs within semiconductor devices using effective and efficient JFET-like test key transistors. The test keys can be applied to any section of a DTI structure in the semiconductor device, such as DTI corners or sides, to determine whether the section reaches a preset DTI depth in the semiconductor device. The test keys can have a specification with a preset source-drain voltage difference, a preset gate voltage, and a predetermined current based on the preset DTI depth. The test keys can have flexible designs based on different preset DTI depths, such as adding or adjusting an insulation layer under the gate or adjusting the preset gate voltage applied on the gate.

Each process, method, and algorithm described in the preceding sections may be embodied in, and fully or partially automated by, code modules executed by one or more computer systems or computer processors comprising computer hardware. The processes and algorithms may be implemented partially or wholly in application-specific circuit.

When the functions disclosed herein are implemented in the form of software functional units and sold or used as independent products, they can be stored in a processor executable non-volatile computer-readable storage medium. Particular technical solutions disclosed herein (in whole or in part) or aspects that contribute to current technologies may be embodied in the form of a software product. The software product may be stored in a storage medium, comprising a number of instructions to cause a computing device (which may be a personal computer, a server, a network device, and the like) to execute all or some steps of the methods of the embodiments of the present application. The storage medium may comprise a flash drive, a portable hard drive, ROM, RAM, a magnetic disk, an optical disc, another medium operable to store program code, or any combination thereof.

Particular embodiments further provide a system comprising a processor and a non-transitory computer-readable storage medium storing instructions executable by the processor to cause the system to perform operations corresponding to steps in any method of the embodiments disclosed above. Particular embodiments further provide a non-transitory computer-readable storage medium configured with instructions executable by one or more processors to cause the one or more processors to perform operations corresponding to steps in any method of the embodiments disclosed above.

Embodiments disclosed herein may be implemented through a cloud platform, a server or a server group (hereinafter collectively the “service system”) that interacts with a client. The client may be a terminal device, or a client registered by a user at a platform, where the terminal device may be a mobile terminal, a personal computer (PC), and any device that may be installed with a platform application program.

The various features and processes described above may be used independently of one another or may be combined in various ways. All possible combinations and sub-combinations are intended to fall within the scope of this disclosure. In addition, certain methods or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

The various operations of example methods described herein may be performed, at least partially, by an algorithm. The algorithm may be comprised in program codes or instructions stored in a memory (e.g., a non-transitory computer-readable storage medium described above). Such algorithm may comprise a machine learning algorithm. In some embodiments, a machine learning algorithm may not explicitly program computers to perform a function but can learn from training data to make a prediction model that performs the function.

The various operations of example methods described herein may be performed, at least partially, by one or more processors that are temporarily configured (e.g., by software) or permanently configured to perform the relevant operations. Whether temporarily or permanently configured, such processors may constitute processor-implemented engines that operate to perform one or more operations or functions described herein.

Similarly, the methods described herein may be at least partially processor-implemented, with a particular processor or processors being an example of hardware. For example, at least some of the operations of a method may be performed by one or more processors or processor-implemented engines. Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an Application Program Interface (API)).

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or sections of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. A semiconductor device, comprising:
a test key transistor comprising a source, a drain, a channel connected to the source and the drain, and a gate; and
a deep trench isolation encroaching into the channel of the test key transistor, wherein:
the test key transistor is associated with a specification including a preset gate voltage, a preset source-drain voltage difference, and a predetermined current, and
the test key transistor is configured to generate a current within a threshold difference from the predetermined current in the channel in response to receiving the preset gate voltage at the gate and the preset source-drain voltage difference at the source and the drain, and the deep trench isolation encroaches into the channel at a preset depth.

2. The semiconductor device according to claim 1, wherein the test key transistor is configured to generate, in the channel, a current more than a threshold difference from the predetermined current in response to the deep trench isolation encroaching into the channel at a depth that is smaller than the preset depth.

3. The semiconductor device according to claim 2, wherein the semiconductor device is configured to be determined as defective in response to the test key transistor generating the current more than the threshold difference from the predetermined current.

4. The semiconductor device according to claim 1, wherein the predetermined current is equal to 0 A, and the threshold difference is in a range between 1 nA and 1 μA.

5. The semiconductor device according to claim 1, wherein:
the test key transistor further comprises an insulation layer below the gate, and
the insulation layer is configured to reduce a cross-sectional area of the channel.

6. The semiconductor device according to claim 1, wherein:
the test key transistor is located on a side of the deep trench isolation, and
the test key transistor is configured to generate the predetermined current in the channel in response to receiving the preset gate voltage at the gate and the preset source-drain voltage difference at the source and the drain, and the side of the deep trench isolation encroaches into the channel at the preset depth.

7. The semiconductor device according to claim 1, further comprising a plurality of test key transistors, each test key transistor corresponding to one of a plurality of sections of the deep trench isolation, wherein:
each of the plurality of test key transistors is configured to generate, in a channel of the each test key transistor, a current more than a threshold difference from the predetermined current in response to the section of the deep trench isolation encroaching into the channel at a depth that is smaller than the preset depth, and
determining that the semiconductor device is defective in response to any of the plurality of test key transistors generating the current more than the threshold difference from the predetermined current.

8. The semiconductor device according to claim 1, wherein:
the test key transistor is located on a corner of the deep trench isolation, and
the test key transistor is configured to generate the predetermined current in the channel in response to receiving the preset gate voltage at the gate and the preset source-drain voltage difference at the source and the drain, and the corner of the deep trench isolation encroaches into the channel at the preset depth.

9. The semiconductor device according to claim 1, wherein:
the semiconductor device is a complementary metal-oxide semiconductor image sensor,
the channel comprises photodiode, and
the deep trench isolation is configured to provide isolation between pixels of the complementary metal-oxide semiconductor image sensor.

10. The semiconductor device according to claim 1, wherein the test key transistor is a p-type junction-gate field transistor or an n-type junction-gate field transistor.

11. A method, comprising:
applying a preset gate voltage on a gate of a test key transistor in a semiconductor device;
applying a preset source-drain voltage difference on a source and a drain of the test key transistor;
measuring a current flowing through a channel of the test key transistor in response to the applied preset gate voltage and preset source-drain voltage difference, wherein the channel is between the source and the drain of the test key transistor;
comparing the measured current with a predetermined current of the test key transistor, wherein the predetermined current corresponds to the preset gate voltage and a preset depth of a deep trench isolation in the semiconductor device and the deep trench isolation encroaches into the channel;
determining whether the deep trench isolation encroaching into the channel at a depth that is different from the preset depth according to the comparison between the measured current and the predetermined current; and
determining that the semiconductor device is defective in response to the deep trench isolation having a different depth from the preset depth.

12. The method according to claim 11, wherein determining whether the deep trench isolation encroaching into the channel a depth that is different from the preset depth according to the comparison between the measured current and the predetermined current comprises:
determining that the measured current is not within a threshold difference from the predetermined current; and
determining that the deep trench isolation encroaches into the channel at a depth that is different from the preset depth in response to the determination that the measured current is not within the threshold difference from the predetermined current.

13. The method according to claim 12, wherein the predetermined current is equal to 0 A, and the threshold difference is in a range between 1 nA and 1 μA.

14. The method according to claim 11, wherein:
the semiconductor device comprises a plurality of the test key transistors, each test key transistor corresponding to one of a plurality of sections of the deep trench isolation, and
determining that the semiconductor device is defective in response to the deep trench isolation encroaching into the channel at a different depth from the preset depth further comprises:
determining that the semiconductor device is defective in response to any of the plurality of sections encroaching into the channel at a different depth from the predetermined depth.

15. The method according to claim 14, wherein the plurality of sections of the deep trench isolation comprises one or more corners of the deep trench isolation.

16. The method according to claim 14, wherein the plurality of sections of the deep trench isolation comprises one or more sides of the deep trench isolation.

17. The method according to claim 1, wherein:
the test key transistor further comprises an insulation layer below the gate, and
the insulation layer is configured to reduce a cross-sectional area of the channel.

18. The method according to claim 11, wherein:
the semiconductor device is a complementary metal-oxide semiconductor image sensor,
the channel comprises photodiode, and
the deep trench isolation is configured to provide isolation between pixels of the complementary metal-oxide semiconductor image sensor.

19. The method according to claim 11, wherein the test key transistor is a p-type junction-gate field transistor or an n-type junction-gate field transistor.

20. A non-transitory computer-readable storage medium storing instructions that, when executed by one or more processors, cause the one or more processors to perform operations comprising:
applying a preset gate voltage on a gate of a test key transistor in a semiconductor device;
applying a preset source-drain voltage difference on a source and a drain of the test key transistor;
measuring a current flowing through a channel of the test key transistor in response to the applied preset gate voltage and preset source-drain voltage difference, wherein the channel is between the source and the drain of the test key transistor;
comparing the measured current with a predetermined current of the test key transistor, wherein the predetermined current corresponds to the preset gate voltage and a preset depth of a deep trench isolation in the semiconductor device and the deep trench isolation encroaches into the channel;
determining whether the deep trench isolation encroaching into the channel at a depth that is different from the preset depth according to the comparison between the measured current and the predetermined current; and
determining that the semiconductor device is defective in response to the deep trench isolation having a different depth from the preset depth.
